(19) United States
(12) Patent Application Publication
(10) Pub. No.: US 2015/0309247 A1
(43) Pub. Date: Oct. 29, 2015

(54) ILLUMINATION APPARATUS

(71) Applicant: KONICA MINOLTA, INC., Chiyoda-ku, Tokyo (JP)

(72) Inventors: Yasuhiro SANDO, Amagasaki-shi, Hyogo-ken (JP); Yusuke HIRAO, Takatsuki-shi, Osaka (JP); Mitsuyoshi NAITO, Toyonaka-shi, Osaka (JP); Junya WAKAHARA, Settsu-shi, Osaka (JP)

(21) Appl. No.: 14/648,154

(22) PCT Filed: Oct. 23, 2013
(86) PCT No.: PCT/JP2013/078674

§ 371 Date: May 28, 2015

(30) Foreign Application Priority Data
Nov. 28, 2012 (JP) 2012-259429

(51) Int. Cl. F21V 8/00

(52) U.S. Cl. CPC G02B 6/0088; G02B 6/0031; G02B 6/0051; G02B 6/005; G02B 6/0078

(57) ABSTRACT

An illumination apparatus includes: a plurality of light emitting panels each having a surface with a light emitting region and a non-light emitting region; a light guiding member having a light incidence face and a light exit face, with the light incidence face opposite to the surface of the light emitting panel; a reflector opposite to the non-light emitting region, and reflecting the light incident on the light guiding member; a light attenuator on the light exit face opposite to the light emitting region, and attenuating the light outputted through an area on the light exit face, the area being opposite to the light emitting region; and a light diffusion member opposite to the light guiding member with a gap therebetween.

### TECHNICAL FIELD

The present invention relates to an illumination apparatus and more specifically to an illumination apparatus including a plurality of light emitting panels disposed in a plane.

### BACKGROUND ART

In recent years, an illumination apparatus including an organic EL (OLED: organic electroluminescence) or similar light emitting panel as a light emitting source, is attracting attention. As there is an increasing demand for large sized illumination apparatuses, there is also a need for light emitting sources having larger areas. A light emitting source may be increased in area by enlarging the area of a light emitting panel that configures the light emitting source. Configuring a light emitting source of an organic EL device or the like increased in area, however, entails a larger apparatus required to produce the device and thus results in increased production cost and reduced yield.

To prevent increased production cost and reduced yield, there is a method known to dispose a plurality of light emitting panels each having a small area. The small light emitting panel can be produced efficiently and inexpensively. In general, however, a light emitting panel is peripherally provided with a non-light emitting region. An illumination apparatus having multiple light emitting panels disposed in a plane has immediately adjacent light emitting panels with a gap (or joint) therebetween. The non-light emitting region, including the gap, can be improved in brightness by disposing a reflector plate or a similar reflection means opposite to the non-light emitting region to reduce unevenness in brightness.

Japanese Patent Laying-Open No. 2005-266285 (PTD 1) discloses an invention of an electro-optical device. The electro-optical device has two small-size substrates with a joint portion therebetween, and one small-size substrate has a side end surface tapered upward or forward and the other small-size substrate has a side end surface tapered downward or reversely. This publication indicates that the electro-optical device allows the joint portion to have a less noticeable gap.

Japanese Patent Laying-Open No. 2005-353564 (PTD 2) discloses an invention of a surface emitting device. The surface emitting device includes a substrate and a surface emitting element formed on the substrate, and also has a light emitting portion and a non-light emitting portion. The substrate includes a light incidence face on which light is incident, and a light exit portion allowing light to exit therefrom. The light exit portion has one or more faces inclined relative to the light incidence face. The one or more inclined faces are provided at a portion corresponding to the non-light emitting portion. The publication indicates that the above configuration can provide an illumination apparatus allowing the non-light emitting portion to have a less noticeable dark portion.

Japanese Patent Laying-Open No. 2009-211886 (PTD 3) discloses an invention of an organic EL device. The organic EL device includes a device substrate and a sealing plate. The device substrate or the sealing plate has an outer major surface to serve as a light exit face for extracting light emitted by an organic light emitting layer. The light exit face includes a parallel portion formed in a light emitting region of the organic light emitting layer located in its upward and downward directions, and an inclined portion formed in a non-light emitting region outer than the light emitting region and inclined relative to the parallel portion. The publication indicates that the organic EL device can reduce spots of light on the light exit face.

### CITATION LIST

### Patent Documents

PTD 1: Japanese Patent Laying-Open No. 2005-266285

PTD 2: Japanese Patent Laying-Open No. 2005-353564

PTD 3: Japanese Patent Laying-Open No. 2009-211886

### SUMMARY OF INVENTION

### Technical Problem

The present invention contemplates an illumination apparatus that can reduce unevenness in brightness and have a less noticeable non-light emitting region.

### Solution to Problem

The present illumination apparatus includes: a plurality of light emitting panels each having a surface with a light emitting region and a non-light emitting region along a perimeter of the light emitting region, and having their respective non-light emitting regions adjacently; a light guiding member having a light incidence face and a light exit face, with the light incidence face opposite to the surface of the light emitting panel, and receiving light from the light emitting region through the light incidence face and allowing the light to exit through the light exit face; a reflector opposite to the non-light emitting region at a side opposite to the surface of the light emitting panel, and reflecting the light that the light guiding member has received from the light emitting region to a side opposite to the light emitting panel with the reflector posed therebetween; a light attenuator on the light exit face opposite to the light emitting region; and a light diffusion member opposite to the light guiding member with a gap therebetween, the light that the light guiding member has received from the light emitting region partially passing through the light attenuator and being reduced thereby in quantity of light, and thus exiting.

### Advantageous Effect of Invention

The present invention can thus provide an illumination apparatus that can reduce unevenness in brightness and have a less noticeable non-light emitting region.

### BRIEF DESCRIPTION OF DRAWINGS

FIG. 1 is a bottom view of an illumination apparatus of an embodiment.

FIG. 2 is a cross section that is taken along an arrowed line II-II shown in FIG. 1 and is seen in a direction indicated by arrows.

FIG. 3 is a plan view of a single one of a plurality of light emitting panels used for an illumination apparatus of an embodiment.

FIG. 4 is a cross section that is taken along an arrowed line IV-IV shown in FIG. 3 and is seen in a direction indicated by arrows.

FIG. 5 is a cross section of two of a plurality of light emitting panels used for an illumination apparatus of an embodiment, the two light emitting panels being disposed immediately adjacently.

FIG. 6 is a perspective view of a single one of a plurality of light emitting panels, a single one of a plurality of light guiding members and a single one of a plurality of light attenuation members, that are used in an illumination apparatus of an embodiment.

FIG. 7 is a cross section of a single one of a plurality of light emitting panels, a single one of a plurality of light guiding members and a single one of a plurality of light attenuation members, that are used in an illumination apparatus of an embodiment.

FIG. 8 is a cross section of an illumination apparatus of an embodiment in operation.

FIG. 9 shows a result of an exemplary experiment performed for an embodiment.

FIG. 10 is a cross section of an illumination apparatus of an embodiment in a second exemplary variation.

FIG. 11 is a cross section of an illumination apparatus of an embodiment in a third exemplary variation.

FIG. 12 is a cross section of an illumination apparatus of an embodiment in a fourth exemplary variation.

### DESCRIPTION OF EMBODIMENTS

Hereinafter reference will be made to the drawings to describe the present invention in embodiments. In describing the embodiments when a number, an amount and the like are referred to, the present invention is not necessarily limited thereto in scope unless otherwise specified. In describing the embodiments, identical or corresponding components are identically denoted and may not be described repeatedly.

Illumination Apparatus 100

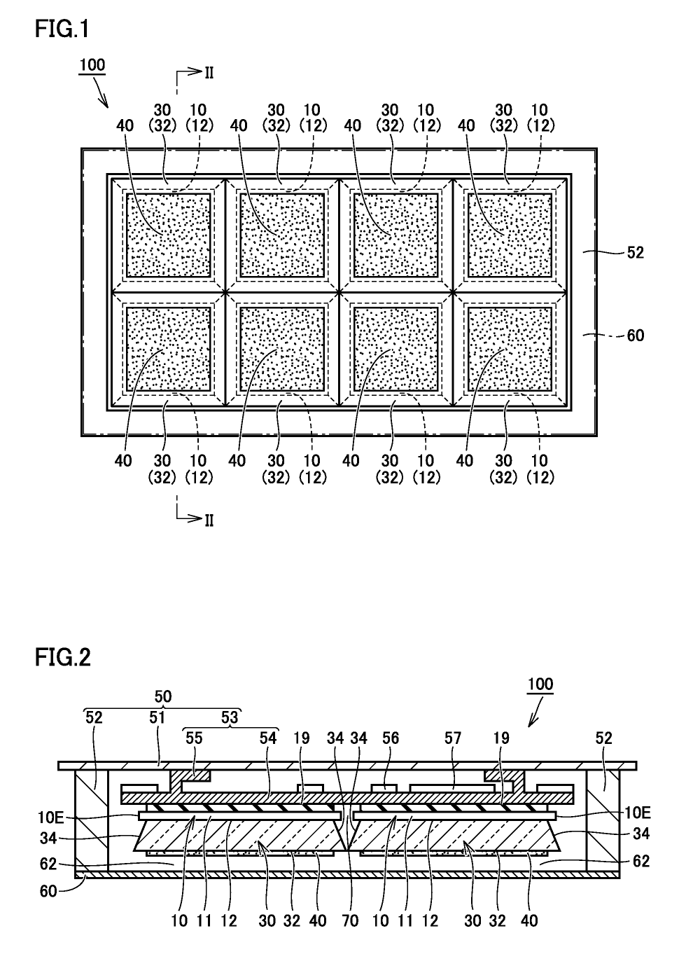

FIG. 1 is a bottom view of an illumination apparatus 100 of an embodiment. FIG. 1 shows illumination apparatus 100 as seen at a front surface 12 (or a light emitting surface) of a light emitting panel 10 used for illumination apparatus 100. FIG. 2 is a cross section that is taken along an arrowed line II-II shown in FIG. 1 and is seen in a direction indicated by arrows.

For the sake of illustration, FIG. 1 shows illumination apparatus 100 with a light diffusion plate 60 (see FIG. 1 and FIG. 2) represented transparently by long dashed short dashed lines and a light guiding member 30 and a light attenuation member 40 represented by a solid line. FIG. 2 shows light emitting panel 10 schematically.

As shown in FIG. 1 and FIG. 2, illumination apparatus 100 includes a plurality of light emitting panels 10, a plurality of light guiding members 30, a plurality of light attenuation members 40, a casing 50 (see FIG. 2), and light diffusion plate 60. In the embodiment illumination apparatus 100 includes eight light emitting panels 10, eight light guiding members 30, and eight light attenuation members 40. Eight light emitting panels 10 are aligned in (a matrix of) two rows and four columns in a plane (or on a single plane) along a direction of a plane. In the embodiment, the plurality of light emitting panels 10 are identically configured each formed to have a perimeter substantially in a square.

Eight light guiding members 30 are each attached to one of eight light emitting panels 10, as will be described more specifically hereinafter. Eight light attenuation members 40 are each attached to one of eight light guiding members 30, as will be described more specifically hereinafter. In the embodiment, illumination apparatus 100 employs light emitting panel 10, light guiding member 30, light attenuation member 40, casing 50, and light diffusion plate 60, as will be described more specifically hereinafter.

Light Emitting Panel 10

The embodiment provides light emitting panel 10 configured of an organic EL device. Light emitting panel 10 may be configured as a light emitting panel in the form of a plane formed of a plurality of light emitting diodes (LED) and a diffuser plate. Light emitting panel 10 may be configured as a light emitting panel in the form of a plane with a cold-cathode tube or the like used. Eight light emitting panels 10 may be configured identically or differently.

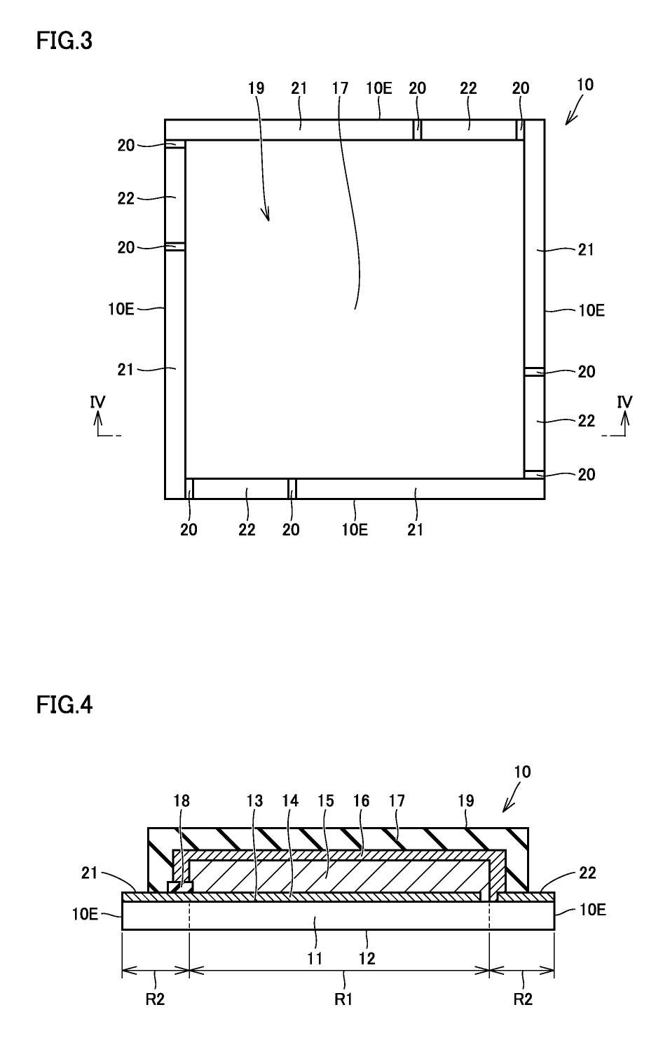

FIG. 3 is a plan view of light emitting panel 10. FIG. 3 shows light emitting panel 10 as seen at a back surface 19 thereof. FIG. 4 is a cross section that is taken along an arrowed line IV-IV shown in FIG. 3 and is seen in a direction indicated by arrows.

With reference to FIG. 3 and FIG. 4, light emitting panel 10 includes a transparent substrate 11 (a cover layer), an anode 14, an organic layer 15, a cathode 16, a sealing member 17, and an insulating layer 18. Transparent substrate 11 forms front surface 12 (or the light emitting surface) of light emitting panel 10, and a peripheral end surface of transparent substrate 11 forms a perimeter 10E of light emitting panel 10. Anode 14, organic layer 15, and cathode 16 are stacked successively on a back surface 13 of transparent substrate 11. Sealing member 17 forms back side 19 of light emitting panel 10.

Transparent substrate 11 is configured for example of a variety of types of glass substrates. Transparent substrate 11 may be configured with a member such as a polyethylene terephthalate (PET), polycarbonate or similar film substrate. Anode 14 is a transparent conductive film. Anode 14 is provided as follows: Indium tin oxide (ITO) or the like is sputtered or the like and thus deposited on transparent substrate 11. Photolithography or the like is employed to pattern the ITO film, as prescribed, to form anode 14. The ITO film that forms anode 14 is patterned and thus divided into two regions to form an electrode lead-out portion 21 (for the anode) and an electrode lead-out portion 22 (for the cathode). Electrode lead-out portion 22 has the ITO film connected to cathode 16.

Organic layer 15 (or a light emitting unit) can be powered to generate visible light. Organic layer 15 may be configured of a single light emitting layer or may be configured of a hole transporting layer, a light emitting layer, a hole blocking layer, an electron transporting layer and the like that are stacked successively. Cathode 16 is aluminum (AL) for example. Cathode 16 is formed through vacuum deposition or the like to cover organic layer 15. To pattern cathode 16, as prescribed, the vacuum deposition may be done through a mask.

To prevent cathode 16 and anode 14 from short-circuiting, insulating layer 18 is provided between cathode 16 and anode 14 closer to electrode lead-out portion 21. Cathode 16 at a portion thereof opposite to the side provided with insulating layer 18 is connected to electrode lead-out portion 22. Insulating layer 18 is provided as follows: for example SiO₂ or the like is sputtered and thus deposited and subsequently photolithographically patterned as desired to cover a portion to insulate anode 14 and cathode 16 from each other.

Sealing member 17 is configured of an insulative resin or glass substrate or the like. Sealing member 17 is formed to protect organic layer 15 against moisture and the like. Sealing member 17 seals anode 14, organic layer 15, and cathode 16 (i.e., members internal to light emitting panel 10) on transparent substrate 11 substantially entirely. Electrode lead-out portion 21 and electrode lead-out portion 22 are exposed from sealing member 17 for electrical connection.

Electrode lead-out portion 21 and anode 14 are identical in material. Electrode lead-out portion 21 is located at the perimeter of light emitting panel 10. Electrode lead-out portion 22 and anode 14 are identical in material. Electrode lead-out portion 22 is also located at the perimeter of light emitting panel 10.

Electrode lead-out portion 21 and electrode lead-out portion 22 are located opposite to each other with organic layer 15 interposed. Between electrode lead-out portion 21 and electrode lead-out portion 22 that are immediately adjacent is provided a division region 20 (see FIG. 3). Electrode lead-out portion 21 and electrode lead-out portion 22 have a patterned wire (not shown) soldered (with silver paste) or the like thereto.

Light emitting panel 10 thus configured has front surface 12 with a light emitting region R1 formed thereon to substantially correspond to a region having organic layer 15 (see FIG. 4), and a non-light emitting region R2 formed thereon to substantially correspond to a region having electrode lead-out portions 21 and 22 (see FIG. 4). Non-light emitting region R2 is located at a perimeter of light emitting region R1 and is annular in geometry.

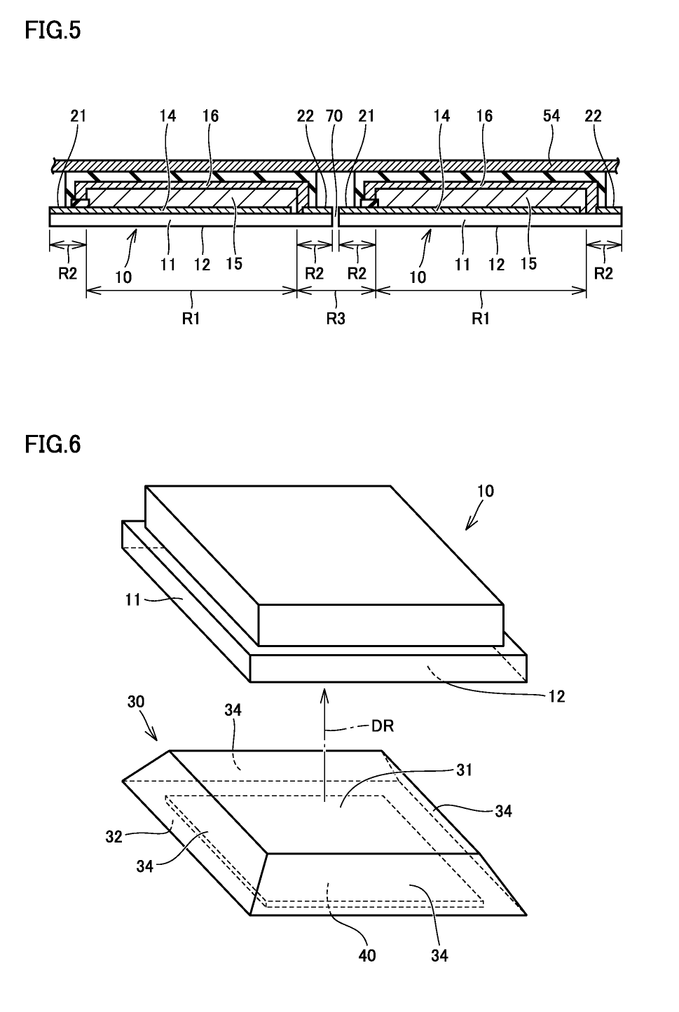

FIG. 5 is a cross section of two light emitting panels 10 disposed immediately adjacently. As shown in FIG. 1, FIG. 2, and FIG. 5, in an embodiment, a plurality of light emitting panels 10 are disposed such that non-light emitting regions R2s (see FIG. 5) are immediately adjacent to each other. Immediately adjacent light emitting panels 10s are spaced by a gap 70 and secured to a panel holding unit 54 of casing 50 (see FIG. 2), as will more specifically be described hereinafter. Immediately adjacent light emitting panels 10s have their respective front surfaces 12 substantially flush with each other. Between immediately adjacent light emitting panels 10s is provided a non-light emitting region R3 including non-light emitting region R2 and gap 70 (see FIG. 5). Non-light emitting region R3 has a width for example of 10 mm.

With reference to FIG. 5, organic layer 15 of light emitting panel 10 is powered by an external power supply through a patterned wire (not shown), electrode lead-out portions 21 and 22, anode 14, and cathode 16. Organic layer 15 generates light, which in turn passes through anode 14 and transparent substrate 11 and exits through front surface 12 (or the light emitting surface) in light emitting region R1.

Light Guiding Member 30 and Light Attenuation Member 40

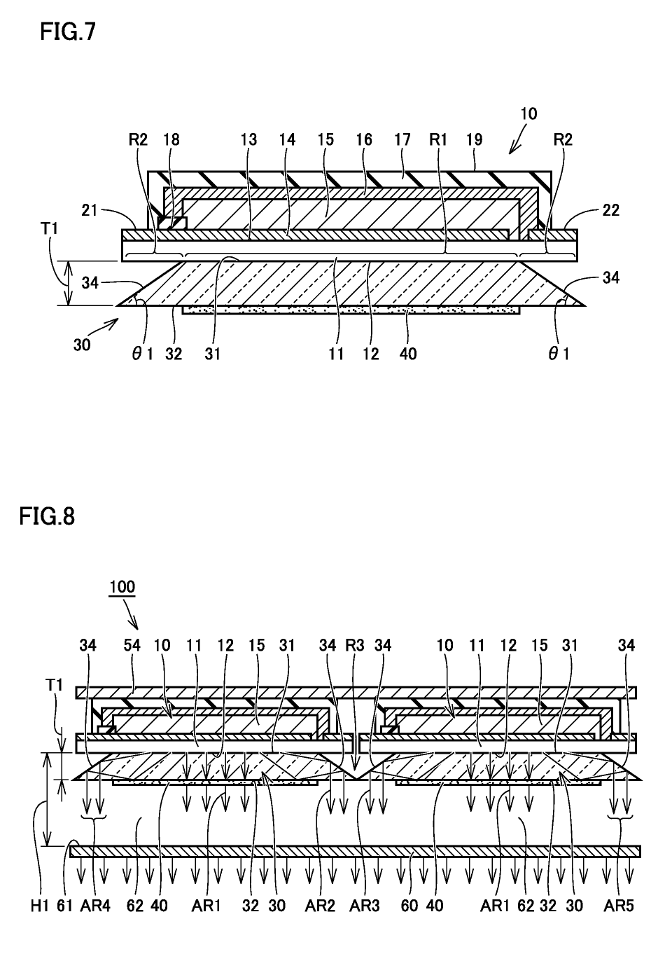

FIG. 6 is a perspective view of light emitting panel 10, light guiding member 30 and light attenuation member 40 used in illumination apparatus 100 (see FIG. 1). FIG. 6 shows light emitting panel 10 and light guiding member 30 separated from each other. FIG. 7 is a cross section of light emitting panel 10, light guiding member 30, and light attenuation member 40. FIG. 7 shows light emitting panel 10 with front surface 12 having light guiding member 30 attached thereto.

With reference to FIG. 6 and FIG. 7 (and FIG. 1 and FIG. 2), the embodiment provides light guiding member 30 formed of a prism and having a light incidence face 31, a light exit face 32, and four reflection faces 34. Light guiding member 30 is trapezoidal in cross section (see FIG. 7) and has a thickness T1 for example of 4 mm Light incidence face 31 and light exit face 32 are formed to be rectangular in geometry and positionally parallel to each other. Light exit face 32 has a larger surface area than light incidence face 31. Light incidence face 31 is opposite to light emitting region R1 (see FIG. 5) formed on front surface 12 of light emitting panel 10 (see FIG. 5).

In the embodiment, an optical adhesive agent (not shown) is provided between light incidence face 31 and transparent substrate 11 (in light emitting region R1). Light guiding member 30 is attached to transparent substrate 11 of light emitting panel 10 via the adhesive agent (see an arrow DR in FIG. 6). The adhesive agent may be introduced as required. The adhesive agent may be replaced with a matching oil or the like. When the adhesive agent or the like is not used, light guiding member 30 and light emitting panel 10 may be secured together by another member so that light guiding member 30 has light incidence face 31 in close contact with transparent substrate 11 (in light emitting region R1).

Light guiding member 30 receives light from light emitting region R1 (see FIG. 5) through light incidence face 31 and allows the light to exit through light exit face 32. Suitably, light incidence face 31 is the same in geometry and size (or surface area) as light emitting region R1 formed on front surface 12 of light emitting panel 10. Light incidence face 31 may be larger or smaller in geometry and size (or surface area) than light emitting region R1.

Four reflection faces 34 are disposed annularly as a whole and form a perimeter of light guiding member 30. Each reflection face 34 is in the form of a trapezoid and is a flat plane in geometry. Four reflection faces 34 connect positionally mutually parallel, paired light incidence faces 31 and light exit face 32 at their respective peripheral edges. Each reflection face 34 extends from the peripheral edge of light incidence face 31 toward that of light exit face 32 and thus inclines to be farther away from light incidence face 31.

Reflection face 34 forms an angle θ1 for example of 30 degrees relative to light exit face 32. Angle θ1 may have a value in a range of 15-70 degrees, as appropriate. When light guiding member 30 is attached to transparent substrate 11 of light emitting panel 10, reflection face 34 functions as a reflector opposite to non-light emitting region R2 at a side opposite to front surface 12 of light emitting panel 10 (see FIG. 7).

Light guiding member 30 formed as described above is formed of a material having an index of refraction for example of approximately 1.4-1.7. Light guiding member 30 is preferably formed of a material having high optical transmittance for visible light, such as glass, quartz, acrylics, polyvinyl chloride, polyethylene, polystyrene, polycarbonate or the like. Light guiding member 30 may be produced in a mold or the like or may be produced such as by cutting a blank of a flat plate.

Light attenuation member 40 is provided on light guiding member 30 at light exit face 32. When light guiding member 30 is attached to transparent substrate 11 of light emitting panel 10, light attenuation member 40 is on light exit face 32 of light guiding member 30 opposite to light emitting region R1. In the embodiment, light attenuation member 40 is formed to be rectangular and has a size corresponding to that of light emitting region R1. In the embodiment, light attenuation member 40 is stuck on a center of light exit face 32. Light attenuation member 40 may be smaller in size than light emitting region R1. It is recommendable that light attenuation member 40 be provided to correspond to at least a portion of light emitting region R1 that is highest in brightness.

Light attenuation member 40 functions as a light attenuator and reduces a quantity of light emitted from light guiding member 30 through light exit face 32. Light attenuation member 40 reduces light incident thereon by a prescribed quantity of light, and thus emits the reduced light. Light attenuation member 40 can be a light diffusion sheet, a half mirror, a light absorption member or the like having an optical transmittance for example of 95% or smaller for visible light, or a similar member that optically decreases quantity of light. Suitably, it is recommendable that light attenuation member 40 be a neutral density (ND) filter. These may be used in combination.

When light attenuation member 40 is the light diffusion sheet, light attenuation member 40 can scatter the light that passes therethrough to thus reduce the light that passes therethrough in quantity of light. When light attenuation member 40 is the half mirror, light attenuation member 40 can transmit a portion of the light that passes therethrough and reflect another portion thereof to thus reduce the light that passes therethrough in quantity of light. When light attenuation member 40 is the light absorption member, light attenuation member 40 can absorb a portion of the light that passes therethrough to thus reduce the light that passes therethrough in quantity of light.

Casing 50 and Light Diffusion Plate 60

Again with reference to FIG. 1 and FIG. 2, casing 50 includes a back panel 51 (see FIG. 2), a sidewall 52, and an attachment 53 (see FIG. 2). Back panel 51 is in the form of a plate. Sidewall 52 is attached to back panel 51 such that the former is suspended from the latter toward a side at which light emitting panel 10 is located. In the embodiment, sidewall 52 as a whole is provided in the form of a frame (see FIG. 1) and located outer than perimeter 10E of light emitting panel 10. Sidewall 52 is disposed to surround the plurality of light emitting panels 10 externally.

Attachment 53 has panel holding portion 54 in the form of a plate, and a securing portion 55 for attaching panel holding portion 54 to back panel 51. Securing portion 55 is attached to back panel 51 with a bolt (not shown) or the like to thus secure panel holding portion 54 to back panel 51.

Panel holding portion 54 has eight light emitting panels 10 attached thereto. Eight light emitting panels 10 may be attached to panel holding portion 54 via double-faced tape or the like, as required. Panel holding portion 54 on a surface thereof opposite to that having light emitting panel 10 thereon is provided with a connector 56, a driver circuit 57 and the like, as required. Connector 56 is used to feed light emitting panel 10 with electric power, and the like. Driver circuit 57 controls light emitting panel 10 drivably.

Light diffusion plate 60 functions as a light diffusion member and is attached to a lower end of sidewall 52. When illumination apparatus 100 is seen at the light emitting surface (see FIG. 1), light diffusion plate 60 has a size (or surface area) covering eight light emitting panels 10 and eight light guiding members 30 entirely.

The light diffusion member preferably for example provides 40 degrees or smaller, more preferably 10-30 degrees or smaller, of dispersion of light. This allows the light diffusion member to pass light more diffusively and thus achieves further reduced unevenness in brightness. Such a light diffusion member can be obtained for example by selecting a light dispersing agent having desired values in particle diameter, particle size distribution, index of refraction and the like, and blending the light dispersing agent with a matrix such as polycarbonate resin to obtain a light diffusion member having a desired degree of dispersion of light.

As has been set forth above, light emitting panel 10 has light guiding member 30 attached thereto. Light guiding member 30 has light attenuation member 40 attached thereto. Light guiding member 30 and light diffusion plate 60 (see FIG. 2) are spaced by a gap 62 (see FIG. 2). Light emitting panel 10 and light diffusion plate 60 have front surface 12 and an upper surface 61 (see FIG. 8), respectively, spaced by a distance H1 (see FIG. 8) for example of 16 mm. When illumination apparatus 100 is used for an advertisement light, a sign or the like, light diffusion plate 60 may be provided with characters, graphics and/or the like as required. Illumination apparatus 100 is configured as described above.

Operation of Illumination Apparatus 100

With reference to FIG. 8, when the plurality of light emitting panels 10 are powered by an external power supply, their respective organic layers 15 emit light. The light generated by organic layer 15 passes through transparent substrate 11 and exits through front surface 12 (or the light emitting surface) in light emitting region R1 (see FIG. 5). The light that exits from light emitting region R1 (see FIG. 5) enters light guiding member 30 through light incidence face 31.

The light having entered light guiding member 30 has a portion passing through light guiding member 30 and exiting through light exit face 32 as it is, and reduced by light attenuation member 40 in quantity of light and thus exiting light attenuation member 40, as indicated by an arrow AR1. The light having entered light guiding member 30 has another portion passing therethrough at a portion closer to non-light emitting region R3, reflected by reflection face 34, and exiting through light exit face 32, as indicated by an arrow AR2. This light does not pass through light attenuation member 40 and does not have its quantity of light reduced by light attenuation member 40.

The light having entered light guiding member 30 has still another portion repeatedly totally reflected by a portion of light guiding member 30 closer to non-light emitting region R3, reflected by reflection face 34, and exiting through light exit face 32, as indicated by an arrow AR3. This light also does not pass through light attenuation member 40 and thus does not have its quantity of light reduced by light attenuation member 40. The light that is reflected by reflection face 34 located outer than light emitting panel 10 (or illumination apparatus 100) also similarly exits through light exit face 32 as it is without passing through light attenuation member 40, as indicated by arrows AR4 and AR5.

The lights indicated by arrows AR1-AR5 subsequently pass through light diffusion plate 60 and thus exit illumination apparatus 100. Such wave-guiding of light is similarly done in eight light emitting panels 10. In illumination apparatus 100, light transmitted through light attenuation member 40 stuck to include a center of light exit face 32 (see arrow AR1) is reduced in quantity of light. The light that exits from a portion corresponding to the light emitting region is reduced to be smaller in brightness than when light attenuation member 40 is not provided. On the other hand, the light that exits from a portion corresponding to the non-light emitting region via reflection by reflection face 34, as indicated by arrows AR2-AR5, is effectively increased in brightness.

Light emitting panel 10 at and around its center provides light reduced in quantity of light and light emitting panel 10 at and around its perimeter allows reflection of light to be effectively utilized to provide an increased quantity of light. The light exiting a portion corresponding the center of light emitting panel 10 and a vicinity thereof and that exiting a portion corresponding the perimeter of light emitting panel 10 and a vicinity thereof have quantities, respectively, of light with a reduced difference therebetween. Illumination apparatus 100 not only can provide a visual effect as if non-light emitting region R3 between immediately adjacent light emitting panels 10s emitted light, but also allows the light emitting surface as a whole to have further reduced unevenness in brightness. Illumination apparatus 100 further enhances this effect by light diffusion plate 60.

Exemplary Experiment

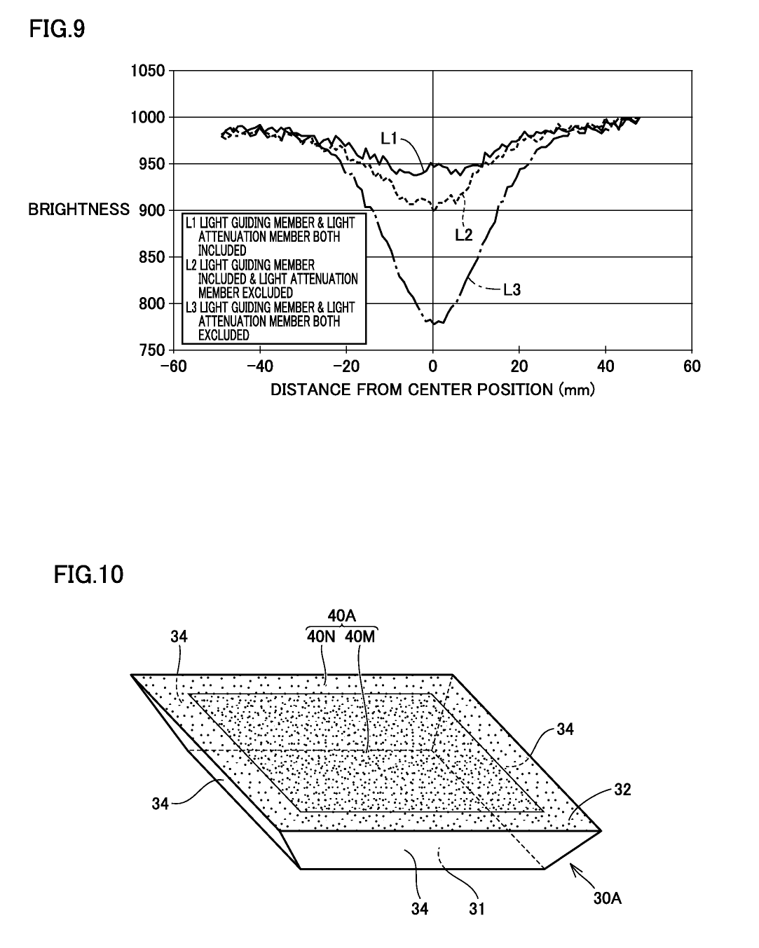

FIG. 9 shows a result of an exemplary experiment performed for an embodiment. For the exemplary experiment, three illumination apparatuses were prepared. One is an illumination apparatus similar in configuration to illumination apparatus 100 of the above described embodiment. This illumination apparatus includes light guiding member 30 having thickness T1 (see FIG. 8) of 4 mm Reflection face 34 forms angle θ1 (see FIG. 7) of 30 degrees relative to light exit face 32. Light emitting panel 10 and light diffusion plate 60 have front surface 12 and upper surface 61, respectively, spaced by distance H1 (see FIG. 8) of 16 mm Transparent substrate 11 has a size of 100 mm×100 mm Light attenuation member 40 has an optical transmittance of 90%.

FIG. 9 has an axis of ordinate representing (a relative value of) brightness at a position having a distance from a center position, as obtained with light emitting region R1 at a center thereof being 1000 in brightness. “Brightness” as referred to herein is a value as observed at a measurement position distant from light diffusion plate 60 by about 100 mm “Center position” as referred to herein is a portion exactly between immediately adjacent light emitting panels 10s. FIG. 9 has an axis of abscissa representing a distance (in mm) from the center position. FIG. 9 indicates a line L1 to indicate a result of a measurement of a distribution in brightness of the illumination apparatus.

FIG. 9 also indicates a line L2 to indicate a result of a measurement of a distribution in brightness of another illumination apparatus. This other illumination apparatus is similar in configuration to the above illumination apparatus except that the former excludes light attenuation member 40. FIG. 9 also indicates a line L3 to indicate a result of a measurement of a distribution in brightness of still another illumination apparatus. Still another illumination apparatus is similar in configuration to the above illumination apparatus except that the former excludes light guiding member 30 and light attenuation member 40.

As can be seen in FIG. 9 from line L1, the illumination apparatus corresponding to the above described embodiment has a variation in brightness within a range of 1000-940. As can be seen in FIG. 9 from line L2, the illumination apparatus including the light guiding member and excluding the light attenuation member has a variation in brightness extended to a range of 1000-900. As can be seen in FIG. 9 from line L3, the illumination apparatus excluding both the light guiding member and the light attenuation member has a variation in brightness extended to a range of 1000-780.

The result of the exemplary experiment also shows that the illumination apparatus of the above described embodiment not only can provide a visual effect as if a non-light emitting region between immediately adjacent light emitting panels emitted light, but also allows a light emitting surface as a whole to have further reduced unevenness in brightness.

First Exemplary Variation

The above described embodiment provides light attenuation member 40 serving as a light attenuator and light guiding member 30 as discrete members (see FIG. 7). The light attenuator may be provided as a portion of light guiding member 30 by surface-processing light exit face 32 of light guiding member 30. Such a light attenuator can be provided for example by sand-blasting light exit face 32 to roughen its surface. Such a light attenuator can alternatively be provided by printing or the like to provide patterning or the like to provide a rough surface. Such a light attenuator can alternatively be provided by molding light guiding member 30 in a die having a small recess and projection at a molding surface corresponding to light exit face 32. The light attenuator may be such a surface-processed portion, and a portion attached as a discrete member such as light attenuation member 40, that are used together.

Second Exemplary Variation

With reference to FIG. 10, in the above embodiment, the light attenuator (light attenuation member 40) is provided partially on the light guiding member at the light exit face opposite to light emitting region R1 (see FIGS. 5 and 7). As shown in FIG. 10, the light attenuator may alternatively be provided on the light guiding member throughout light exit face 32 opposite to both light emitting region R1 (see FIGS. 5 and 7) and non-light emitting region R2 (see FIGS. 5 and 7). In that case, when the light guiding member is attached to the transparent substrate of the light emitting panel, the light guiding member has a light exit face shaped opposite to both light emitting region R1 and non-light emitting region R2.

FIG. 10 shows a light guiding member 30A having light exit face 32 with a light attenuating portion 40A thereon. Light attenuation portion 40A includes a center portion 40M and a peripheral portion 40N. Light attenuation portion 40A is provided as a portion of light guiding member 30A by surface-processing light exit face 32 of light guiding member 30A.

When light guiding member 30A is attached to the transparent substrate of the light emitting panel, center portion 40M is opposite to light emitting region R1 (see FIGS. 5 and 7). Center portion 40M corresponds to a portion of light attenuation portion 40A that is provided opposite to light emitting region R1. When light guiding member 30A is attached to the transparent substrate of the light emitting panel, peripheral portion 40N is opposite to non-light emitting region R2 (see FIGS. 5 and 7). Peripheral portion 40N corresponds to a portion of light attenuation portion 40A that is provided opposite to non-light emitting region R2.

Optical transmittance in center portion 40M is lower than optical transmittance in peripheral portion 40N. In other words, center portion 40M has a property less easily passing light therethrough than peripheral portion 40N. This configuration can also achieve a function and effect similar to that of the above embodiment. Center portion 40M higher in optical diffusivity than peripheral portion 40N can also provide a similar function and effect.

A light diffusion sheet or the like that has optical transmittance or optical diffusivity corresponding to center portion 40M and peripheral portion 40N and is stuck on light exit face 32, can also provide a similar function and effect. It may be configured to provide optical transmittance gradually increased as seen at a vicinity of center portion 40M toward peripheral portion 40N. This configuration allows in-plane brightness to vary smoothly to achieve more natural emission of light. It may be configured to provide optical diffusivity gradually decreased as seen at a vicinity of center portion 40M toward peripheral portion 40N. This configuration can also achieve a similar function and effect.

Third Exemplary Variation

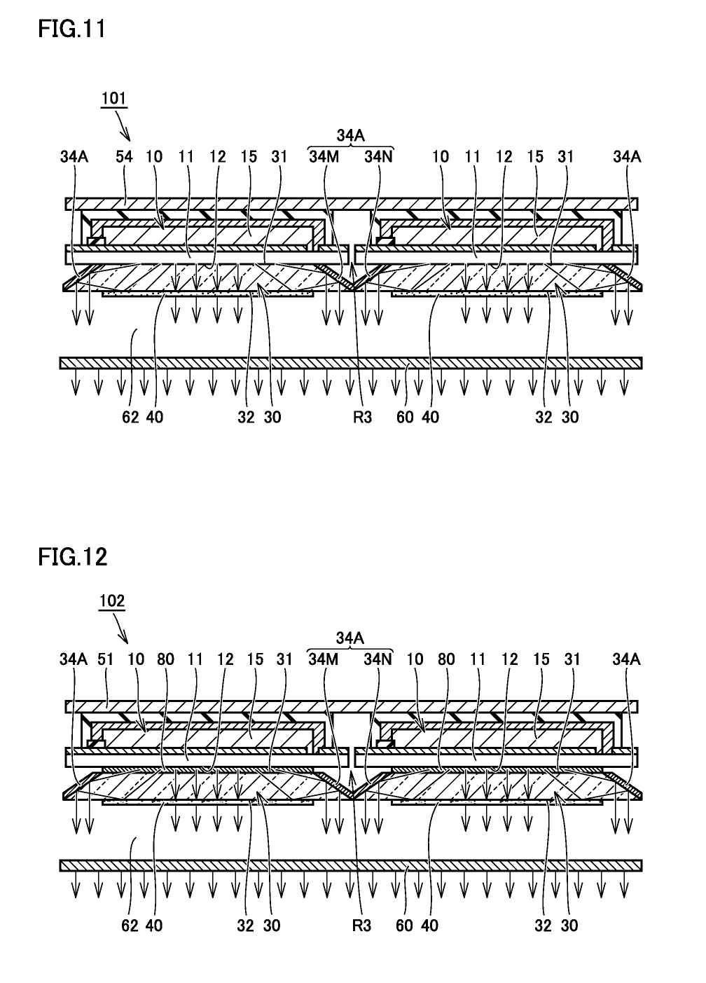

FIG. 11 is a cross section of an illumination apparatus 101 in the embodiment in a third exemplary variation. In the above described embodiment, illumination apparatus 100 has light guiding member 30 with reflection face 34 functioning as a reflector. Reflection face 34 is provided as a portion of light guiding member 30. Reflection face 34 may have the function as the reflector implemented by a member provided independently of light guiding member 30.

Illumination apparatus 101 has the configuration of illumination apparatus 100 and further includes a reflection member 34A. Reflection member 34A is configured for example of a thin plate of metal. Reflection member 34A is provided at a portion corresponding to non-light emitting region R3 and is V-letter shaped by sheet-metal working or the like to have bent portions 34M and 34N. Reflection member 34A can substitute for or supplement the reflection function of reflection face 34 (see FIG. 7).

When reflection member 34A is formed of material of metal, it includes aluminum (aluminum material of high brightness), iron, copper and stainless steel for example. When reflection member 34A is formed of material other than material of metal, it includes a seal having a reflection function, and polycarbonate, acrylics, ABS, PET and other similar resin materials, and when reflection member 34A is formed of resin material, these optical members can be produced by injection molding. To improve the reflection function, these materials may have their surfaces coated with a film of silver, gold, aluminum, or an alloy thereof. Instead of reflection member 34A, light guiding member 30 may have reflection face 34 with silver deposited thereon in the form of a film through vapor deposition. Other than this, aluminum may be deposited in the form of a film through vapor deposition, silver and aluminum plating may be provided, or coating or the like may be provided to deposit a film.

Fourth Exemplary Variation

FIG. 12 is a cross section of an illumination apparatus 102 in the embodiment in a fourth exemplary variation. Illumination apparatus 102 has the configuration of illumination apparatus 101 (see FIG. 11) and further includes a light diffusion layer 80 (a light diffuser). Light diffusion layer 80 is provided between light emitting region R1 of light emitting panel 10 and light guiding member 30. The configuration of illumination apparatus 100 (see FIG. 8) plus light diffusion layer 80 may be used.

The light diffuser may be the light guiding member 30 light incidence face 31 provided with recess and projection. In that case, the light diffuser is provided as a portion of light guiding member 30. The light diffuser may be the light guiding member 30 light incidence face 31 coated with fine particles. The light diffuser may have regions intermingled that are different in optical diffusivity.

Light emitting panel 10 emits light having a spectrally varying light distribution characteristic. In other words, light emitting panel 10 emits light having a color high in rectilinearly and a color low in rectilinearly. As there is a difference in rectilinearly depending on color, a color drift is prone to arise between the light transmitted through light guiding member 30 and thus exiting as it is and the light totally reflected inside light guiding member 30, propagated to the non-light emitting region, and thus exiting.

Light diffusion layer 80 (or the light diffuser) provided between light emitting region R1 of light emitting panel 10 and light guiding member 30 allows light guiding member 30 to receive light through light diffusion layer 80 that is widely diffused by light diffusion layer 80 as the light passes therethrough. This allows each spectrum's light distribution characteristic to be a Lambertian distribution of light and can thus reduce a tendency (or deviation) attributed to a difference in wavelength. This allows light of any uniform color to exit through light exit face 32.

For example, this can prevent light exiting light guiding member 30 from mostly being observed to be white while partially being observed to be yellowish. When light diffusion layer 80 has a surface with recess and projection, light diffusion layer 80 can further diffuse light to allow the light to behave as if a secondary light source existed there. When light diffusion layer 80 has therein regions intermixed that have a difference in reflectance, the difference in reflectance allows different light to proceed in a frontward direction to also achieve a more balanced brightness distribution.

While the present invention has thus been described in embodiments, exemplary variations and exemplary experiments, it should be understood that the embodiments, exemplary variations and exemplary experiments disclosed herein have been described for the purpose of illustration only and in a non-restrictive manner in any respect. The scope of the present invention in the art is defined by the terms of the claims, and is intended to include any modifications within the meaning and scope equivalent to the terms of the claims.

### REFERENCE SIGNS LIST

10: light emitting panel; 10E: perimeter; 11: transparent substrate; 12: front surface; 13: back surface; 14: anode; 15: organic layer; 16: cathode; 17: sealing member; 18: insulating layer; 19: back side; 20: division region; 21, 22: electrode lead-out portion; 30, 30A: light guiding member; 31: light incidence face; 32: light exit face; 34: reflection face (reflector); 34A: reflection member (reflector); 34M, 34N: bent portion; 40: light attenuation member (light attenuator); 40A: light attenuator; 40M: center portion; 40N: peripheral portion; 50: casing; 51: back panel; 52: sidewall; 53: attachment; 54: panel holding portion; 55: securing portion; 56: connector; 57: driver circuit; 60: light diffusion plate; 61: upper surface; 62: gap; 70: gap; 80: light diffusion layer; 100, 101, 102: illumination apparatus; AR1, AR2, AR3, AR4, AR5, DR: arrow; H1: distance; L1, L2, L3: line; R1: light emitting region; R2, R3: non-light emitting region; T1: thickness.

1. An illumination apparatus comprising:
a plurality of light emitting panels each having a surface with a light emitting region and a non-light emitting region along a perimeter of the light emitting region, and having their respective non-light emitting regions adjacently;
a light guiding member having a light incidence face and a light exit face, with the light incidence face opposite to the surface of the light emitting panel, and receiving light from the light emitting region through the light incidence face and outputting the light through the light exit face;
a reflector opposite to the non-light emitting region, and reflecting the light incident on the light guiding member to a side opposite to the light emitting panel;
a light attenuator on the light exit face opposite to the light emitting region, and attenuating the light output through an area on the light exit face, the area being opposite to the light emitting region; and
a light diffusion member opposite to the light guiding member with a gap therebetween.

2. The illumination apparatus according to claim 1, wherein the light attenuator scatters light that passes therethrough to thus attenuate the light that passes therethrough.

3. The illumination apparatus according to claim 1, wherein the light attenuator is provided as a portion of the light guiding member by surface-processing the light exit face.

4. The illumination apparatus according to claim 1, wherein the light attenuator includes a half mirror on the light exit face.

5. The illumination apparatus according to claim 1, wherein the light attenuator includes a light absorption member on the light exit face.

6. The illumination apparatus according to claim 1, wherein the reflector includes a reflection member discrete from the light guiding member.

7. the illumination apparatus according to claim 1, wherein a light diffuser is provided between the light emitting region and the light guiding member.

8. The illumination apparatus according to claim 1, wherein the light attenuator includes a center portion opposite to the light emitting region and a peripheral portion opposite to the non-light emitting region, and optical transmittance in the center portion is lower than optical transmittance in the peripheral portion.

9. The illumination apparatus according to claim 2, wherein the light attenuator is provided as a portion of the light guiding member by surface-processing the light exit face.

10. The illumination apparatus according to claim 1, wherein the reflector forms a perimeter of the light guiding member.

11. The illumination apparatus according to claim 1, wherein the light diffusion member diffuses light attenuated by the attenuator and light reflected by the reflector.

12. The illumination apparatus according to claim 2, wherein a light diffuser is provided between the light emitting region and the light guiding member.

13. The illumination apparatus according to claim 5, wherein a light diffuser is provided between the light emitting region and the light guiding member.

14. The illumination apparatus according to claim 2, wherein the light attenuator includes a center portion opposite to the light emitting region and a peripheral portion opposite to the non-light emitting region, and optical transmittance in the center portion is lower than optical transmittance in the peripheral portion.

15. The illumination apparatus according to claim 4, wherein the light attenuator includes a center portion opposite to the light emitting region and a peripheral portion opposite to the non-light emitting region, and optical transmittance in the center portion is lower than optical transmittance in the peripheral portion.

16. The illumination apparatus according to claim 5, wherein the light attenuator includes a center portion opposite to the light emitting region and a peripheral portion opposite to the non-light emitting region, and optical transmittance in the center portion is lower than optical transmittance in the peripheral portion

17. The illumination apparatus according to claim 6, wherein: the light attenuator includes a center portion opposite to the light emitting region and a peripheral portion opposite to the non-light emitting region, and optical transmittance in the center portion is lower than optical transmittance in the peripheral portion.

18. The illumination apparatus according to claim 7, wherein the light attenuator includes a center portion opposite to the light emitting region and a peripheral portion opposite to the non-light emitting region, and optical transmittance in the center portion is lower than optical transmittance in the peripheral portion.

19. The illumination apparatus according to claim 8, wherein the light attenuator includes a center portion opposite to the light emitting region and a peripheral portion opposite to the non-light emitting region, and optical transmittance in the center portion is lower than optical transmittance in the peripheral portion.

20. The illumination apparatus according to claim 9, wherein the light attenuator includes a center portion opposite to the light emitting region and a peripheral portion opposite to the non-light emitting region, and optical transmittance in the center portion is lower than optical transmittance in the peripheral portion.
